(19) United States
(12) Patent Application Publication
(10) Pub. No.: US 2026/0271590 A1
(43) Pub. Date: Sep. 10, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: In-Bae KIM, YONGIN-SI (KR); Beom Soo PARK, YONGIN-SI (KR); Eunji Lim, YONGIN-SI (KR); Jae Ik LIM, YONGIN-SI (KR); Jung-Hyun CHO, YONGIN-SI (KR)

(21) Appl. No.: 19/428,933

(22) Filed: Dec. 22, 2025

(30) Foreign Application Priority Data
Mar. 7, 2025 (KR) 10-2025-0029765

(51) Int. Cl. H10K 59/80; G06F 3/041; H10K 59/40

(52) U.S. Cl. CPC H10K 59/873; G06F 3/0412; H10K 59/40

(57) ABSTRACT

A display device includes a substrate including a display area and a non-display area, a pixel circuit portion disposed on the substrate and overlapping the display area, an encapsulation layer disposed on the pixel circuit portion, and a touch sensing portion disposed on the encapsulation layer. The touch sensing portion includes a first sensing insulating layer, a second sensing insulating layer disposed on the first sensing insulating layer, a third sensing insulating layer disposed on the second sensing insulating layer, a fourth sensing insulating layer disposed on the third sensing insulating layer, and a sensing electrode disposed between the first sensing insulating layer and the second sensing insulating layer. In the non-display area, an end of the fourth sensing insulating layer is positioned inward from an end of the second sensing insulating layer.

### CROSS-REFERENCE TO RELATED APPLICATIONS

This application claims priority under 35 U.S.C. § 119 to Korean Patent Application No. 10-2025-0029765, filed on Mar. 7, 2025, the disclosure of which is incorporated by reference herein in its entirety.

### TECHNICAL FIELD

Embodiments of the present disclosure relate to a display device and an electronic device including the same.

### DISCUSSION OF RELATED ART

A display device is a device that displays images, and includes, for example, a liquid crystal display (LCD), an organic light emitting diode (OLED) display, and the like. Such display devices are used in various electronic devices such as, for example, mobile phones, navigation systems, digital cameras, electronic books, portable game consoles, or various terminals.

### SUMMARY

Embodiments are directed to providing a display device with improved reliability in a region where a substrate is bent, and an electronic device including the same.

A display device according to an embodiment includes a substrate including a display area and a non-display area, a pixel circuit portion disposed on the substrate and overlapping the display area, an encapsulation layer disposed on the pixel circuit portion, and a touch sensing portion disposed on the encapsulation layer. The touch sensing portion includes a first sensing insulating layer, a second sensing insulating layer disposed on the first sensing insulating layer, a third sensing insulating layer disposed on the second sensing insulating layer, a fourth sensing insulating layer disposed on the third sensing insulating layer, and a sensing electrode disposed between the first sensing insulating layer and the second sensing insulating layer. In the non-display area, an end of the fourth sensing insulating layer is positioned inward from an end of the second sensing insulating layer.

An end of the third sensing insulating layer may be positioned inward from the end of the second sensing insulating layer.

The end of the third sensing insulating layer and the end of the fourth sensing insulating layer may overlap.

The end of the third sensing insulating layer and the end of the fourth sensing insulating layer may form the same inclined surface.

The second sensing insulating layer may cover the end of the first sensing insulating layer.

The end of the third sensing insulating layer may be positioned inward from the end of the first sensing insulating layer.

The end of the fourth sensing insulating layer may be positioned inward from the end of the first sensing insulating layer.

The first sensing insulating layer and the third sensing insulating layer may include an inorganic insulating material, and the second sensing insulating layer and the fourth sensing insulating layer may include an organic insulating material.

The second sensing insulating layer and the fourth sensing insulating layer may include the same material.

The touch sensing portion may further include a lower insulating layer positioned between the first sensing insulating layer and the encapsulation layer.

Ends of the lower insulating layer and the first sensing insulating layer may overlap.

The display device may further include a bending protection layer overlapping at least a portion of the second sensing insulating layer, and the bending protection layer may cover at least a portion of an upper surface of the second sensing insulating layer.

A portion of the substrate that overlaps the bending protection layer may have a curved shape.

The display device may further include a light blocking layer positioned in the non-display area, and a minimum distance from the light blocking layer to the second sensing insulating layer may be greater than a minimum distance from the light blocking layer to the fourth sensing insulating layer.

The light blocking layer may be an area where at least two of a first color filter, a second color filter, and a third color filter having different colors overlap.

A display device according to an embodiment includes a substrate including a display area and a non-display area, a pixel circuit portion disposed on the substrate, an encapsulation layer disposed on the pixel circuit portion, and a touch sensing portion disposed on the encapsulation layer. The touch sensing portion includes a first sensing insulating layer, a second sensing insulating layer disposed on the first sensing insulating layer, a third sensing insulating layer disposed on the second sensing insulating layer, a fourth sensing insulating layer disposed on the third sensing insulating layer, and a sensing electrode disposed between the first sensing insulating layer and the second sensing insulating layer. In the non-display area, an end of the fourth sensing insulating layer is positioned on an upper surface of the second sensing insulating layer.

The end of the third sensing insulating layer and the end of the fourth sensing insulating layer may overlap.

The end of the third sensing insulating layer may be positioned inward from the end of the second sensing insulating layer, and the end of the fourth sensing insulating layer may be positioned inward from the end of the second sensing insulating layer.

The touch sensing portion may further include a lower insulating layer positioned between the first sensing insulating layer and the encapsulation layer, and ends of the lower insulating layer and the first sensing insulating layer may overlap.

The display device may further include a bending protection layer overlapping at least a portion of the second sensing insulating layer, and a portion of the substrate that overlaps the bending protection layer may have a curved shape.

An electronic device according to an embodiment includes a display device and a cover window positioned on the display device. The display device includes a substrate including a display area and a non-display area, a pixel circuit portion disposed on the substrate, an encapsulation layer disposed on the pixel circuit portion, and a touch sensing portion disposed on the encapsulation layer. The touch sensing portion includes a first sensing insulating layer, a second sensing insulating layer disposed on the first sensing insulating layer, a third sensing insulating layer disposed on the second sensing insulating layer, a fourth sensing insulating layer disposed on the third sensing insulating layer, and a sensing electrode disposed between the first sensing insulating layer and the second sensing insulating layer. In the non-display area, an end of the fourth sensing insulating layer is positioned on an upper surface of the second sensing insulating layer.

The electronic device may further include a protective layer positioned on a rear surface of the substrate.

According to embodiments, a display device with improved reliability in a region where a substrate is bent and an electronic device including the same may be provided.

### BRIEF DESCRIPTION OF THE DRAWINGS

The above and other features of the present disclosure will become more apparent by describing in detail embodiments thereof with reference to the accompanying drawings.

FIG. 1 is a block diagram of an electronic device according to an embodiment.

FIG. 2 shows schematic diagrams of electronic devices according to various embodiments.

FIG. 3 is a perspective view schematically illustrating an electronic device according to an embodiment.

FIG. 4 is an exploded perspective view of an electronic device according to an embodiment.

FIG. 5 is a plan view illustrating some components of a display device according to an embodiment.

FIG. 6 is an enlarged plan view illustrating a non-display area according to an embodiment.

FIG. 7 is an enlarged cross-sectional view of a portion of a display device according to an embodiment.

FIG. 8 is a schematic cross-sectional view of a pixel positioned in a display area.

FIG. 9 is a schematic cross-sectional view of a partial area of a non-display area.

FIGS. 10, 11, and 12 are cross-sectional views of partial areas in a non-display area, respectively.

FIGS. 13, 14, and 15 are plan views of sensing insulating layers in a non-display area according to an embodiment, respectively.

FIGS. 16, 17, 18, and 19 are cross-sectional views of a display area, respectively.

FIG. 20 is a cross-sectional view illustrating a layered structure of a non-display area according to an embodiment.

### DETAILED DESCRIPTION

Embodiments of the present disclosure will be described more fully hereinafter with reference to the accompanying drawings. Like reference numerals may refer to like elements throughout the accompanying drawings.

It will be further understood that terms such as “comprise,” “include,” and “have,” when used herein, specify a presence of stated features, integers, steps, operations, elements, and/or components, but do not preclude the presence or addition of one or more other features, integers, steps, operations, elements, components, and/or groups thereof.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Throughout the specification, "in a plan view" means that the target part is viewed from above, and "in a cross-section" means that a cross-section obtained by vertically cutting the target part is viewed from the side.

Embodiments of the present disclosure relate to a light emitting display device having an improved stacked touch sensing structure configured to improve mechanical reliability in the bending region of a foldable display. For example, the display device includes a non-display area with a touch sensing portion formed from a plurality of stacked sensing insulating layers. The structure and arrangement of these layers are configured to reduce strain concentration and prevent cracking or delamination, for example, near the transition zone adjacent to the bending area.

According to embodiments, the touch sensing portion includes a layered stack of inorganic and organic insulating materials, such as, for example, a lower sensing insulating layer, a first sensing insulating layer, a second sensing insulating layer, a third sensing insulating layer, and a fourth sensing insulating layer, each having distinct material properties and termination positions. For example, in an embodiment, the second sensing insulating layer formed of an organic insulating material is extended further into the bending area than the adjacent inorganic insulating layers, such that it functions as a compliant buffer to absorb bending stress. A bending protection layer, also composed of an organic material, is disposed selectively on the second sensing insulating layer in a manner that avoids overlapping brittle inorganic edges, thereby improving reliability.

By carefully controlling the lateral termination points and vertical stacking order of the sensing insulating layers and the bending protection layer, the display device according to embodiments may mitigate mechanical failures such as crack propagation and delamination, which are typically induced by repeated folding in portable electronics. As a result, the disclosed structure enables improved durability of the touch sensing portion and overall reliability of the foldable display device without compromising the electrical functionality of the touch sensor or the flexibility of the display.

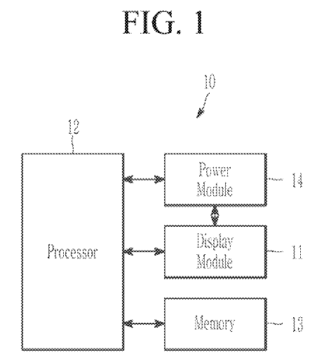

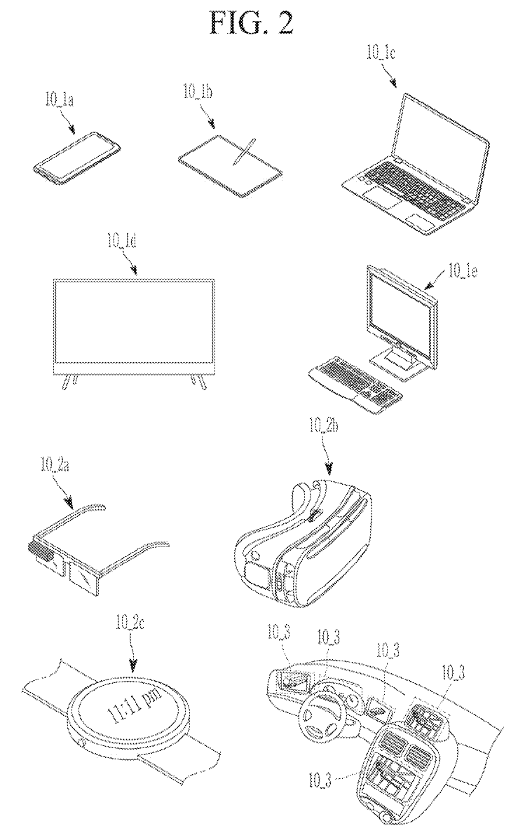

Hereinafter, an electronic device according to an embodiment will be described with reference to FIGS. 1 and 2. FIG. 1 is a block diagram of an electronic device according to an embodiment.

Referring to FIG. 1, an electronic device 10 according to an embodiment may include a display module 11, a processor 12, a memory 13, and a power module 14, and the like.

The display module 11 may include a display panel, a driver, and the like. The display panel may include pixels that display images and may provide a display screen. The driver may process signals to display images on the display screen of the display device and supply them to the display device. The driver may be provided in the form of an integrated circuit chip.

The processor 12 may include at least one of a central processing unit (CPU), an application processor (AP), a graphic processing unit (GPU), a communication processor (CP), an image signal processor (ISP), and a controller.

Data information desirable for the operation of the processor 12 or the display module 11 may be stored in the memory 13. In case that the processor 12 executes an application stored in the memory 13, image data signals and/or input control signals are transmitted to the display module 11, and the display module 11 may process the provided signals to display images through the display screen.

The power module 14 may include a power supply module such as a power adapter or a battery device and a power conversion module that converts power supplied by the power supply module to generate power desirable for operation of the electronic device 10.

At least one of the respective components of the electronic device 10 described above may be included in the display device according to embodiments. In addition, some of the individual modules functionally included in one module may be included in the display device, and others may be provided separately from the display device. For example, the display device may include the display module 11, and the processor 12, memory 13, and power module 14 may be provided in the form of other devices in the electronic device 10 rather than the display device.

FIG. 2 shows schematic diagrams of electronic devices according to various embodiments.

The display device according to embodiments may be applied to various electronic devices. Referring to FIG. 2, various electronic devices to which the display device according to embodiments is applied may include electronic devices for image display such as a smartphone 10_1a, a tablet computer 10_1b, a laptop 10_1c, a TV 10_1d, and a computer monitor 10_1e. In addition, the electronic device may include wearable electronic devices including display modules such as smart glasses 10_2a, head mounted displays 10_2b, and smart watches 10_2c, and automotive electronic devices 10_3 including display modules or display devices such as instrument panels, center fascia, CID (Center Information Display) disposed on dashboards, and room mirror displays of automobiles.

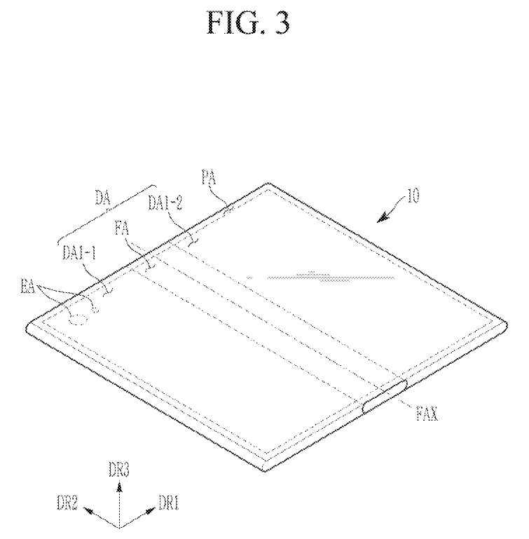

Hereinafter, the structure of the electronic device 10 according to an embodiment will be described with reference to FIG. 3. FIG. 3 is a perspective view schematically illustrating an electronic device according to an embodiment. An embodiment according to FIG. 3 illustrates a foldable display device having a structure in which the electronic device is folded through a folding axis.

Referring to FIG. 3, in an embodiment, the electronic device 10 may be a foldable display device. The electronic device 10 may be folded outward or inward with respect to a folding axis FAX. When folded outward with respect to the folding axis FAX, the display surfaces of the electronic device 10 are respectively positioned outward in a third direction DR3 so that images may be displayed in both directions. When folded inward with respect to the folding axis FAX, the display surfaces are not visible to the user.

In an embodiment, the electronic device 10 may include a display area DA, a component area EA, and a non-display area PA. The display area DA may include a 1-1 display area DA1-1, a 1-2 display area DA1-2, and a folding area FA. The 1-1 display area DA1-1 and the 1-2 display area DA1-2 may be positioned on the left and right sides, respectively, with respect to (or centered on) the folding axis FAX, and the folding area FA may be positioned between the 1-1 display area DA1-1 and the 1-2 display area DA1-2. When folded outward with respect to the folding axis FAX, the 1-1 display area DA1-1 and the 1-2 display area DA1-2 are positioned on both sides in the third direction DR3 and may display images in both directions. When folded inward with respect to the folding axis FAX, the 1-1 display area DA1-1 and the 1-2 display area DA1-2 are not visible to the user.

In an embodiment, the electronic device 10 has a rectangular shape in a plan view and the length of one side along the first direction DR1 is longer than the length of one side along the second direction DR2, as illustrated in FIG. 3. However, embodiments are not limited thereto. For example, according to embodiments, the length of one side along the first direction DR1 may be shorter than the length of one side along the second direction DR2, and the folding axis FAX is parallel to the first direction DR1.

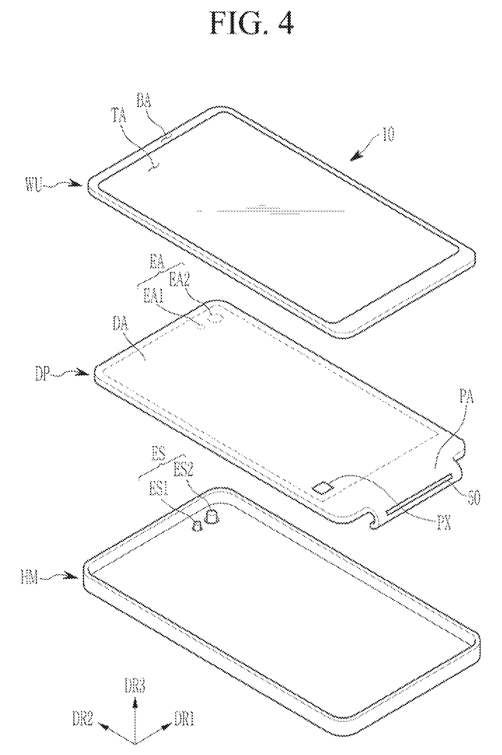

Next, a specific structure of the electronic device 10 according to an embodiment will be described with reference to FIG. 4. FIG. 4 is an exploded perspective view of the electronic device 10 according to an embodiment.

Referring to FIG. 4, the electronic device 10 according to an embodiment may display images toward a third direction DR3 on a display surface parallel to each of a first direction DR1 and a second direction DR2. The display surface on which images are displayed may correspond to a front surface of the electronic device 10 and may correspond to a front surface of a cover window WU. The images may include dynamic images (e.g., video) as well as still images.

In an embodiment, the front surface (or upper surface) and the rear surface (or lower surface) of each member are defined based on the direction in which images are displayed. The front surface and the rear surface oppose each other in the third direction DR3, and the normal direction of each of the front surface and the rear surface may be parallel to the third direction DR3. The separation distance in the third direction DR3 between the front surface and the rear surface may correspond to the thickness of the display panel in the third direction DR3.

The electronic device 10 according to an embodiment may detect a user's externally applied input. The user's input may include various types of external inputs such as a part of the user's body, light, heat, or pressure. The present disclosure is not limited thereto. The user's input may be provided in various forms, and the electronic device 10 may also detect a user's input applied to a side or rear surface of the electronic device 10 according to the structure of the electronic device 10.

The electronic device 10 may include a cover window WU and a housing HM. In an embodiment, the cover window WU and the housing HM may be combined to form an exterior of the electronic device 10.

The cover window WU may include an insulating panel. For example, the cover window WU may include glass, plastic, or a combination thereof.

The front surface of the cover window WU may define the front surface of the electronic device 10. The transmission area TA may be an optically transparent area. For example, the transmission area TA may be an area having a visible light transmittance of about 90% or more.

The blocking area BA may define the shape of the transmission area TA. The blocking area BA may be adjacent to the transmission area TA and may surround the transmission area TA. The blocking area BA may be an area having a relatively low light transmittance compared to the transmission area TA. The blocking area BA may include an opaque material that blocks light. The blocking area BA may have a color. The blocking area BA may be defined by a bezel layer provided separately from a transparent substrate defining the transmission area TA, or may be defined by an ink layer formed by being inserted or colored in the transparent substrate.

The housing HM may be coupled to the cover window WU. The cover window WU may be disposed on the front surface of the housing HM. The housing HM may be coupled to the cover window WU to provide an accommodation space.

The housing HM may include a material having relatively high rigidity. For example, the housing HM may include glass, plastic, or metal, or may include a plurality of frames and/or plates including combinations thereof. The housing HM may reliably protect the components of the electronic device 10 accommodated in the internal space from external impact.

The display device DP and the optical element ES may be accommodated in an accommodation space provided between the housing HM and the cover window WU.

The display device DP may include pixels PX that display images and a driver 50, and the pixels PX are positioned in the display area DA and the component area EA. The display device DP may include a front surface including the display area DA and the non-display area PA. In an embodiment, the display area DA and the component area EA are areas where images are displayed including pixels, and may also be areas where external input is detected with a touch sensor positioned above the pixels in the third direction DR3.

The transmission area TA of the cover window WU may at least partially overlap the display area DA and the component area EA of the display device DP. For example, the transmission area TA may overlap the front surfaces of the display area DA and the component area EA, or may overlap at least portions of the display area DA and the component area EA. Accordingly, a user may view images through the transmission area TA or provide external input based on the images. However, the present disclosure is not limited thereto. For example, the area where images are displayed and the area where external input is detected may be separated from each other.

The non-display area PA of the display device DP may at least partially overlap the blocking area BA of the cover window WU. The non-display area PA may be an area covered by the blocking area BA. The non-display area PA may be adjacent to the display area DA and may surround the display area DA. Images are not displayed in the non-display area PA, and driving circuits or driving wiring for driving the display area DA may be disposed therein. The non-display area PA may be positioned outside the display area DA and may include an area including connection wiring and a bending area.

In an embodiment, a portion of the non-display area PA of the display device DP may be curved. A portion of the non-display area PA faces the rear surface of the electronic device 10, so that the blocking area BA shown on the front surface of the electronic device 10 may be reduced.

In addition, the component area EA of the display device DP may include a first component area EA1 and a second component area EA2. The first component area EA1 and the second component area EA2 may be at least partially surrounded by the display area DA. Although the first component area EA1 and the second component area EA2 are shown as being spaced apart from each other, they are not limited thereto and may be at least partially connected. The first component area EA1 and the second component area EA2 may be areas where optical elements ES using infrared rays, visible light, or sound are disposed below them.

In the display area DA (hereinafter also referred to as a main display area) and the component area EA, a plurality of light emitting diodes and a plurality of pixel circuit portions that generate and transmit light emitting current to each of the plurality of light emitting diodes are formed. Here, one light emitting diode and one pixel circuit portion are called a pixel PX. In the display area DA and the component area EA, one pixel circuit portion and one light emitting diode may be formed in a one-to-one relationship.

The first component area EA1 may include a transmission portion through which light and/or sound may transmit and a display portion including a plurality of pixels. The transmission portion is positioned between adjacent pixels and is composed of a layer through which light and/or sound may transmit. The transmission portion may be positioned between adjacent pixels, and in some embodiments, a layer through which light of a specific wavelength band (for example, visible light) does not transmit may overlap the first component area EA1. The number of pixels per unit area (hereinafter also referred to as resolution) of pixels included in the display area DA (hereinafter also referred to as normal pixels) and the number of pixels per unit area of pixels included in the first component area EA1 (hereinafter also referred to as first component pixels) may be the same.

The second component area EA2 includes an area composed of a transparent layer to allow light transmission (hereinafter also referred to as a light transmission area), and the light transmission area does not have conductive layers or semiconductor layers positioned therein, and may have a structure that does not block light by being formed to include openings where layers containing light-blocking materials, for example, pixel defining layers and/or at least two color filters, overlap positions corresponding to the second component area EA2. The number of pixels per unit area of pixels included in the second component area EA2 (hereinafter also referred to as second component pixels) may be smaller than the number of pixels per unit area of normal pixels included in the display area DA. As a result, the resolution of the second component pixels may be lower than the resolution of the normal pixels.

The driver 50 may be mounted in the non-display area PA, and may be mounted on a bending portion or positioned on one side of the bending portion. The driver 50 may be provided in the form of a chip.

The driver 50 may be electrically connected to the display area DA and the component area EA to transmit electrical signals to pixels in the display area DA and the component area EA. For example, in an embodiment, the driver 50 may provide data signals to pixels PX disposed in the display area DA. In an embodiment, the driver 50 may include a touch driving circuit and may be electrically connected to touch sensors disposed in the display area DA and/or the component area EA. The driver 50 may be designed to include various circuits in addition to the circuits described above or to provide various electrical signals to the display area DA.

A pad portion may be positioned at an end of the non-display area PA, and may be electrically connected to a flexible printed circuit board (FPCB) including a driving chip through the pad portion. Here, the driving chip positioned on the flexible printed circuit board may include various driving circuits for driving the electronic device 10 or connectors for power supply. According to embodiments, a rigid printed circuit board (PCB) may be used instead of the flexible printed circuit board.

The optical element ES may be disposed below the display device DP. The optical element ES may include a first optical element ES1 overlapping the first component area EA1 and a second optical element ES2 overlapping the second component area EA2. The first optical element ES1 may use infrared rays, and in this case, a layer through which light such as visible light does not transmit may overlap the first component area EA1.

The first optical element ES1 may be an electronic element using light or sound. For example, the first optical element ES1 may be a sensor that receives and uses light like an infrared sensor, a sensor that outputs and detects light or sound to measure distance or recognize fingerprints, a small lamp that outputs light, or a speaker that outputs sound. In the case of electronic elements using light, light of various wavelength bands, such as visible light, infrared light, and ultraviolet light, may be used.

The second optical element ES2 may be at least one of a camera, an infrared camera (IR camera), a dot projector, an infrared illuminator (IR illuminator), and a time-of-flight sensor (ToF sensor).

In an embodiment, the optical element ES may additionally include a light detection sensor or a heat detection sensor. The optical element ES may detect external objects received through the front surface or provide sound signals such as voice to the user through the front surface. In addition, the optical element ES may include a plurality of components and is not limited to any one embodiment.

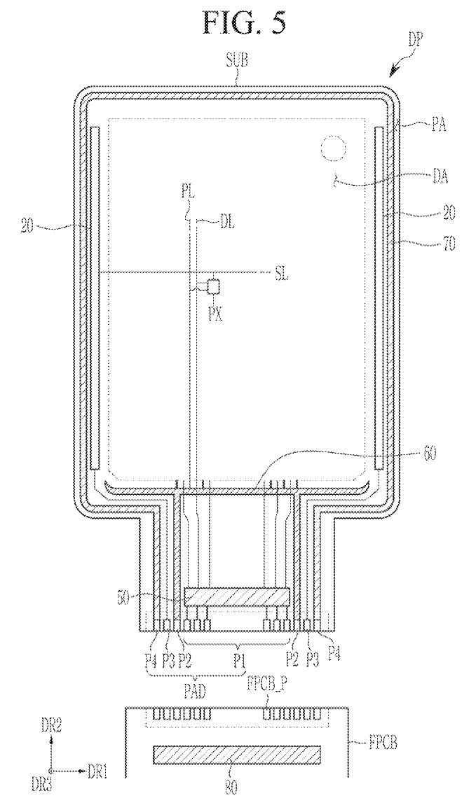

FIG. 5 is a plan view illustrating some components of a display device according to an embodiment.

Referring to FIG. 5, the display device DP includes a plurality of pixels PX positioned in the display area DA. The plurality of pixels PX may be disposed in the display area DA. Each pixel PX includes a light emitting element and a pixel circuit portion connected to the light emitting element. Each pixel PX emits, for example, red, green, blue, or white light, and may include, for example, an organic light emitting diode.

The display device DP may include a plurality of signal lines and a pad portion. The plurality of signal lines may include scan lines SL extending in a first direction DR1, data lines DL and driving voltage lines PL extending in a second direction DR2, and the like.

The scan driver 20 is positioned on the left and right sides of the display area DA, and generates and transmits scan signals to each pixel PX through scan lines SL. The pixel PX may receive scan signals together from two scan drivers 20 positioned on the left and right sides.

The pad portion PAD (hereinafter also referred to as a circuit board pad portion) is disposed at an end of the non-display area PA of the display device DP and may include a plurality of terminals P1, P2, P3, and P4. The pad portion PAD may be exposed without being covered by an insulating layer and electrically connected to a flexible printed circuit board (FPCB). The pad portion PAD may be electrically connected to a pad portion FPCB_P of the flexible printed circuit board FPCB. The flexible printed circuit board FPCB may transmit signals or power from an IC driving chip 80 to the pad portion PAD.

The IC driving chip 80 changes a plurality of image signals transmitted from an external source into a plurality of image data signals and transmits the changed signals to the data driver 50 through the terminal P1. In addition, the IC driving chip 80 may receive vertical synchronization signals, horizontal synchronization signals, and clock signals, generate control signals for controlling the driving of the scan driver 20 and the data driver 50, and transmit them to each through terminals P3 and P1. The IC driving chip 80 transmits a driving voltage ELVDD to the driving voltage supply wiring 60 through the terminal P2. In addition, the IC driving chip 80 may transmit a common voltage ELVSS to each of the common voltage supply wirings 70 through the terminal P4.

The data driver 50 is disposed in the non-display area PA, generates data voltages to be applied to each pixel PX, and transmits them to each data line DL. The data driver 50 may be disposed on a side of the display device DP, for example, between the pad portion PAD and the display area DA.

The driving voltage supply wiring 60 is disposed in the non-display area PA. For example, the driving voltage supply wiring 60 may be disposed between the data driver 50 and the display area DA. The driving voltage supply wiring 60 provides driving voltage to the pixels PX.

The common voltage supply wiring 70 is disposed in the non-display area PA. The common voltage supply wiring 70 may have a form surrounding the substrate SUB. The common voltage supply wiring 70 transmits a common voltage ELVSS to an electrode (e.g., cathode) of the light emitting element included in the pixel PX.

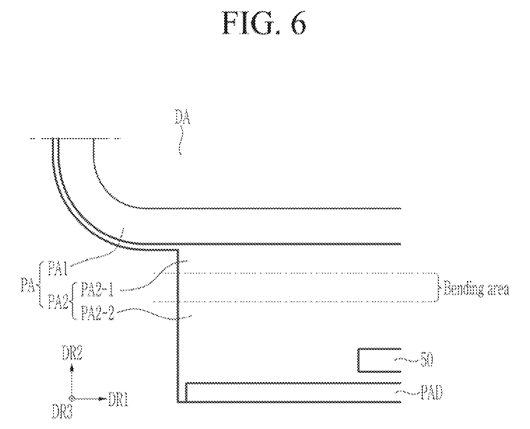

Hereinafter, the structure of the non-display area of the display device will be described in further detail with reference to FIG. 6. FIG. 6 is an enlarged plan view illustrating the non-display area in more detail according to an embodiment.

The non-display area PA may include a first non-display area PA1 positioned outside the display area DA and a second non-display area PA2 including the driver 50, the pad portion PAD, connection wiring, and a bending area.

The first non-display area PA1 is positioned surrounding the outside of the display area DA and may be positioned between the display area DA and the second non-display area PA2. The encapsulation layer ENC is positioned in the display area DA, extends to the non-display area PA, and may extend to between the display area DA and the bending area among the non-display area PA.

The second non-display area PA2 includes a 2-1 non-display area PA2-1 and a 2-2 non-display area PA2-2 positioned on both sides around the bending area.

The 2-1 non-display area PA2-1 extends from the edge of the first non-display area PA1 to the bending area, and the 2-2 non-display area PA2-2 may extend from the end of the bending area through the driver 50 to the pad portion PAD. The driver 50 may further include a driver pad portion for electrical connection with the driver 50 mounted in chip form. The pad portion PAD located at the end of the 2-2 non-display area PA2-2 may also be referred to as a circuit board pad portion and is a part electrically connected to pads of a flexible printed circuit board (FPCB).

In an embodiment, the 2-2 non-display area PA2 encompasses both the electrical functionality and mechanical flexibility necessary for a foldable configuration. The 2-1 non-display area PA2-1, which resides between the display area DA and the bending area, may accommodate insulating layers and touch sensing structures that extend from the display area DA. As the display substrate bends, mechanical stress tends to concentrate in this transitional area. According to embodiments, the layered structure of the touch sensing portion, for example, the positioning of the third sensing insulating layer IL3 and the fourth sensing insulating layer IL4, may be configured in a spatial arrangement that reduces the likelihood of stress-induced failures.

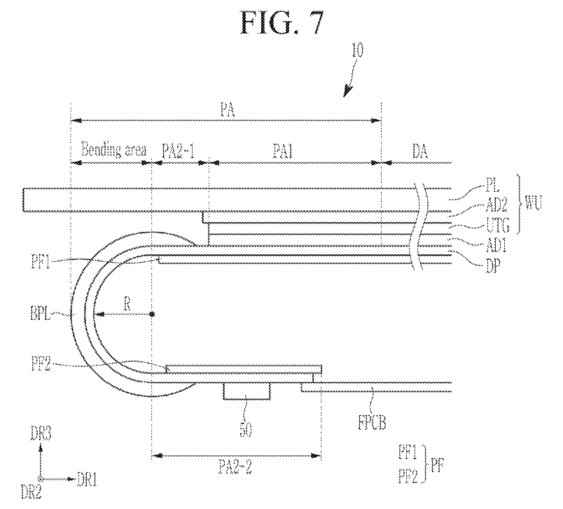

For example, in an embodiment, a bending protection layer BPL (see FIG. 7), which is disposed on the second sensing insulating layer IL2, is spaced apart from the third and fourth sensing insulating layers IL3 and IL4 to avoid directly overlapping with them. Because the third sensing insulating layer IL3 is formed of an inorganic material, it may be more susceptible to crack initiation when exposed to concentrated stress. By terminating the third and fourth sensing insulating layers IL3 and IL4 inward from the end of the second sensing insulating layer IL2 and positioning the bending protection layer BPL to cover only the second sensing insulating layer IL2, the bending protection layer BPL according to embodiments may support the overlying layers without propagating stress to brittle components. This structural separation may contribute to improved resistance against delamination and fracture in the folded state, improving mechanical reliability in the 2-1 non-display area PA2-1.

The light emitting display panel having the above planar structure forms a light emitting display device with the actual bending area folded backward, and the folded state will be described further with reference to FIG. 7.

FIG. 7 is an enlarged cross-sectional view of a portion of a display device according to an embodiment. The display device may be housed in a housing in a backward folded state as shown in FIG. 7.

The electronic device 10 according to an embodiment may include a display device DP, a first adhesive layer AD1, a cover glass UTG, a second adhesive layer AD2, and a protective layer PL. The cover glass UTG, the second adhesive layer AD2, and the protective layer PL may be included in the cover window WU described above.

The bending area may further include a bending protection layer BPL, and the bending protection layer BPL may include an organic material.

In an embodiment, the bending protection layer BPL is disposed in the bending area, which may reinforce mechanical stability. The bending protection layer BPL may be formed of an organic material, which offers greater flexibility and resilience than inorganic layers. As a result, in an embodiment, the bending protection layer BPL may absorb mechanical stress during bending without transmitting excessive strain to overlying or adjacent layers.

As described further with respect to the touch sensing structure, in an embodiment, the bending protection layer BPL may be spaced apart from the third sensing insulating layer IL3 and the fourth sensing insulating layer IL4, which are more brittle due to their material composition. In an embodiment, by covering only the second sensing insulating layer IL2, which is an organic layer, the bending protection layer BPL may avoids overlapping the crack-prone IL3 layer. This configuration may reduce the risk of crack formation and delamination during repeated bending, and may result in improved display reliability in flexible and foldable devices.

The 2-2 non-display area PA2-2, which extends from the end of the bending area among the non-display area PA through the driver 50 to the end of the pad portion PAD, is positioned on the rear surface of the substrate included in the display device DP and may be hidden from the front. In addition, the driver 50 positioned in the 2-2 non-display area PA2-2 and the flexible printed circuit board FPCB extending from the 2-2 non-display area PA2-2 are also positioned on the rear surface and may be hidden from the front.

A protective layer PF that protects the substrate SUB may be positioned on the rear surface of the substrate SUB. In an embodiment, the rear protective layer PF is not formed in the bending area. As a result, the bending area may be easily folded. Referring to FIG. 7, in an embodiment, the protective layer PF may include a first protective layer PF1 overlapping the display area DA and portions of the non-display area PA (the first non-display area PA1 and the 2-1 non-display area PA2-1) and a second protective layer PF2 overlapping the 2-2 non-display area PA2-2. Although the two protective layers PF1 and PF2 adjacent in the third direction DR3 are shown as being relatively far apart (e.g., separated from each other) in FIG. 7, they may actually be in a state of being almost attached.

The first adhesive layer AD1 and the second adhesive layer AD2 may include optically transparent adhesives or pressure-sensitive adhesives. The first adhesive layer AD1 and the second adhesive layer AD2 may include adhesive materials such as, for example, acrylics polymers, ethylene vinyl acetate polymers, nitriles polymers, silicone rubbers, butyl rubber, styrene block copolymers, vinyl ethers polymers, urethane polymers, and epoxy polymers, and the like.

The cover glass UTG and the protective layer PL are included in the cover window WU and are positioned above the display device DP to protect the display device DP from external impact.

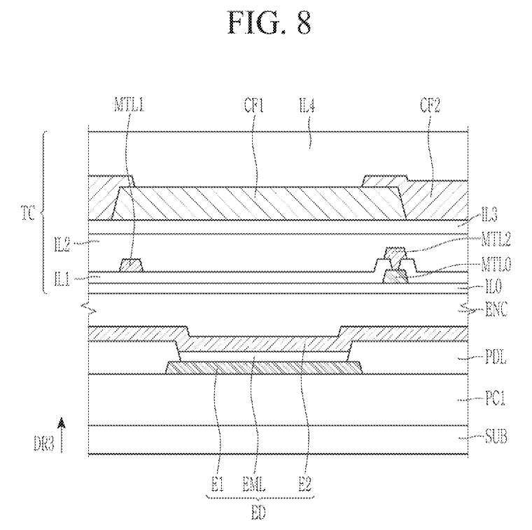

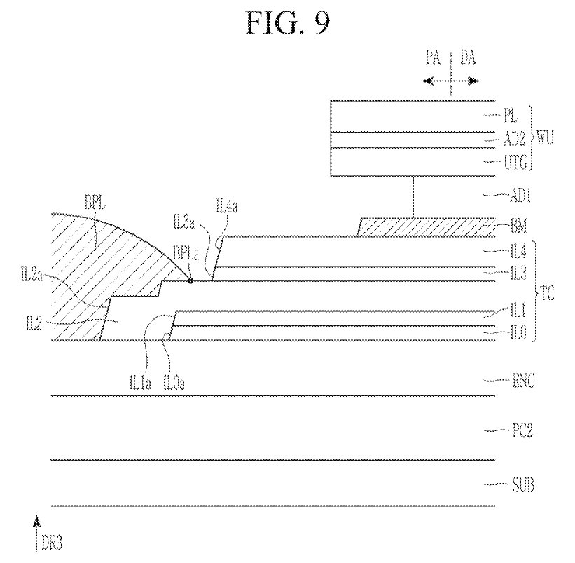

Hereinafter, the cross-sectional structure of a pixel area and the cross-sectional structure of the non-display area according to an embodiment will be described with reference to FIGS. 8 and 9. FIG. 8 is a schematic cross-sectional view of a pixel positioned in the display area, and FIG. 9 is a schematic cross-sectional view of a partial area of the non-display area.

Referring first to FIG. 8, a display device according to an embodiment may include a substrate SUB, a pixel circuit portion PC1 positioned on the substrate SUB, a light emitting element ED positioned on the pixel circuit portion PC1, an encapsulation layer ENC positioned above the light emitting element ED, and a touch sensing portion TC positioned on the encapsulation layer ENC.

The substrate SUB according to an embodiment may include a flexible material that may be bent, such as plastic or polyimide, or may include thin glass.

A pixel circuit portion PC1 electrically connected to the light emitting element ED may be positioned on the substrate SUB. The pixel circuit portion PC1 may include a plurality of metal layers and a plurality of insulating layers, and the specific structure will be described further below.

A pixel defining layer PDL may be positioned on the pixel circuit portion PC1. The pixel defining layer PDL may overlap edges of the first electrode E1 and may be spaced apart from a central portion of the first electrode E1. The pixel defining layer PDL may partition the formation position of the light emitting layer EML so that the light emitting layer EML may be positioned on a portion where the upper surface of the first electrode E1 is exposed.

The pixel defining layer PDL may be an organic insulating layer including one or more materials such as, for example, polyimide, polyamide, acrylic resin, benzocyclobutene, and phenol resin, and according to embodiments, the pixel defining layer PDL may be formed as a black pixel defining layer including black pigment.

The light emitting layer EML may be positioned in the opening of the pixel defining layer PDL. The light emitting layer EML may include organic materials that emit red, green, blue, or other light. The light emitting layer EML that emits red, green, and blue light may include low molecular weight or high molecular weight organic materials. Although the light emitting layer EML is shown as a single layer in FIG. 8, auxiliary layers such as, for example, an electron injection layer, an electron transport layer, a hole transport layer, and a hole injection layer may also be included above and below the light emitting layer EML. A hole injection layer and a hole transport layer may be positioned below the light emitting layer EML, and an electron transport layer and an electron injection layer may be positioned above the light emitting layer EML.

The second electrode E2 may be positioned above the pixel defining layer PDL and the light emitting layer EML. The second electrode E2 is also referred to as a cathode electrode. The second electrode E2 may include transparent conductive oxides including, for example, ITO (Indium Tin Oxide), IZO (Indium Zinc Oxide), IGZO (Indium Gallium Zinc Oxide), and ITZO (Indium Tin Zinc Oxide), and the like. In addition, the second electrode E2 may have translucent characteristics, and in this case, may form a micro-cavity together with the first electrode E1. According to the micro-cavity structure, light of a specific wavelength is emitted upward due to the spacing and characteristics between the two electrodes, and as a result, red, green, or blue may be displayed.

The first electrode E1, the light emitting layer EML, and the second electrode E2 may form one light emitting element ED.

An encapsulation layer ENC is positioned above the second electrode E2. The encapsulation layer ENC may include at least one inorganic layer and at least one organic layer, and according to an embodiment, may have a triple-layer structure including a first inorganic encapsulation layer, an organic encapsulation layer, and a second inorganic encapsulation layer.

The encapsulation layer ENC may protect the light emitting layer EML including organic materials from moisture or oxygen, and the like that may be introduced into the device. According to embodiments, the encapsulation layer ENC may include a structure in which inorganic layers and organic layers are sequentially further stacked.

A touch sensing portion TC may be positioned on the encapsulation layer ENC.

The touch sensing portion TC according to an embodiment may include a plurality of sensing insulating layers IL1, IL2, IL3, IL4, and IL0 and sensing electrodes MTL1, MTL2, and MTL0.

A lower sensing insulating layer IL0 may be positioned on the encapsulation layer ENC. The lower sensing insulating layer IL0 may be formed as an inorganic insulating layer. The inorganic material included in the inorganic insulating layer may be at least one of, for example, silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. According to embodiments, the lower sensing insulating layer IL0 may be omitted.

A sensing electrode connection portion MTL0, a first sensing insulating layer IL1, and a plurality of sensing electrodes MTL1 and MTL2 may be positioned above the lower sensing insulating layer IL0. The plurality of sensing electrodes MTL1 and MTL2 may be positioned on the same layer, and the sensing electrode connection portion MTL0 may be positioned on a different layer from the plurality of sensing electrodes MTL1 and MTL2.

The sensing electrode connection portion MTL0, the first sensing insulating layer IL1, and the plurality of sensing electrodes MTL1 and MTL2 may constitute a sensing sensor. The sensing sensor may be classified into types such as, for example, resistive type, capacitive type, electro-magnetic type, and optical type, and the like. The sensing sensor according to an embodiment may use a capacitive type sensor.

The first sensing insulating layer IL1 may be positioned between the sensing electrode connection portion MTL0 and the plurality of sensing electrodes MTL1 and MTLB. The first sensing insulating layer IL1 may include an inorganic insulating material. The inorganic insulating material may include at least one of, for example, silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

A plurality of sensing electrodes MTL1 and MTL2 may be positioned on the first sensing insulating layer IL1. The plurality of sensing electrodes MTL1 and MTL2 may include a plurality of first sensing electrodes MTL1 and a plurality of second sensing electrodes MTL2. The first sensing electrode MTL1 and the second sensing electrode MTL2 may be electrically insulated. The first sensing insulating layer IL1 may include an opening that exposes the upper surface of the sensing electrode connection portion MTL0. Through the opening of the first sensing insulating layer IL1, the sensing electrode connection portion MTL0 may be connected to the second sensing electrode MTL2 to electrically connect two adjacent second sensing electrodes MTL2. In addition, the sensing electrode connection portion connecting the first sensing electrode MTL1 may be formed on the same layer as the first sensing electrode MTL1 and the second sensing electrode MTLB.

The plurality of sensing electrodes MTL1 and MTL2 may include conductive materials with good conductivity. For example, the plurality of sensing electrodes MTL1 and MTL2 may include metals or metal alloys such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta), and the like. The plurality of sensing electrodes MTL1 and MTL2 may be a single layer or multiple layers. The plurality of sensing electrodes MTL1 and MTL2 may include openings so that light emitted from the light emitting diodes may be emitted upward without interference. According to embodiments, the plurality of sensing electrodes MTL1 and MTL2 may be a triple layer including an upper layer, a middle layer, and a lower layer, and the upper layer and lower layer may include titanium (Ti), and the middle layer may include aluminum (Al).

A second sensing insulating layer IL2 may be positioned on the plurality of sensing electrodes MTL1 and MTL2. The second sensing insulating layer IL2 may include an organic insulating material. The organic insulating material may include, for example, at least one of acetate-based compounds, acrylic resins, polyimide resins, polyamide resins, and Alq₃[Tris(8-hydroxyquinolinato)aluminum].

The second sensing insulating layer IL2 may provide a flat upper surface while covering the plurality of sensing electrodes MTL1 and MTL2 and the first sensing insulating layer IL1. The second sensing insulating layer IL2 may substantially overlap the entire surface of the substrate SUB.

A third sensing insulating layer IL3 may be positioned on the second sensing insulating layer IL2. The third sensing insulating layer IL3 may protect the second sensing insulating layer IL2. The third sensing insulating layer IL3 may include an inorganic insulating material. The inorganic insulating material may include at least one of, for example, silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

Color filters CF1 and CF2 may be positioned on the third sensing insulating layer IL3.

The color filters CF1 and CF2 include a red color filter that transmits red light, a green color filter that transmits green light, and a blue color filter that transmits blue light. Each color filter CF1 and CF2 may be positioned to overlap in a plan view with the first electrode E1 of the light emitting diode. Because light emitted from the light emitting layer EML may be emitted while being changed to a corresponding color as it passes through the color filter, all light emitted from the light emitting layer EML may have the same color. However, the light emitting layer EML exhibits light of different colors, and the displayed color may be enhanced by passing through color filters of the same color.

A plurality of color filters CF1 and CF2 may overlap in non-light emitting areas corresponding to between adjacent pixels. As illustrated, an embodiment in which two color filters overlap, and one color filter is a blue color filter and the other color filter is a red color filter, is provided. However, embodiments are not limited thereto. For example, in an embodiment, at least two color filters among red color filters, green color filters, and blue color filters may overlap in the non-light emitting area.

A fourth sensing insulating layer IL4 covering the color filters CF1 and CF2 may be positioned above the color filters CF1 and CF2. The fourth sensing insulating layer IL4 may planarize the upper surface of the touch sensing portion TC. The fourth sensing insulating layer IL4 may be a transparent organic insulating layer including one or more materials such as, for example, polyimide, polyamide, acrylic resin, benzocyclobutene, phenol resin, and acetate-based compounds. The fourth sensing insulating layer IL4 and the second sensing insulating layer IL2 according to an embodiment may include the same insulating material.

Hereinafter, the stacked structure of the touch sensing portion positioned in the non-display area will be described with reference to FIG. 9.

Referring to FIG. 9, a peripheral circuit portion PC2 and an encapsulation layer ENC positioned on the substrate SUB may be positioned in the non-display area PA. The peripheral circuit portion PC2 may include a plurality of insulating layers and a plurality of signal lines extending from the pixel circuit portion (PC1 of FIG. 8). The encapsulation layer ENC positioned in the non-display area PA may extend from the encapsulation layer ENC positioned in the display area DA. At least a portion of the encapsulation layer ENC positioned in the non-display area PA may include only inorganic layers.

A touch sensing portion TC may be positioned on the encapsulation layer ENC.

A lower sensing insulating layer IL0 and a first sensing insulating layer IL1 extending from the display area DA may be positioned in the non-display area PA. Ends of the lower sensing insulating layer IL0 and the first sensing insulating layer IL1 may be aligned with each other. The end IL0a of the lower sensing insulating layer IL0 and the end IL1a of the first sensing insulating layer IL1 may form one side surface. The end IL0a of the lower sensing insulating layer IL0 and the end IL1a of the first sensing insulating layer IL1 may form the same inclined surface. The end IL0a of the lower sensing insulating layer IL0 and the end IL1a of the first sensing insulating layer IL1 may have side surfaces inclined with the same slope. The lower sensing insulating layer IL0 and the first sensing insulating layer IL1 may include inorganic insulating materials.

In embodiments, aligning the ends of the lower sensing insulating layer IL0 and the first sensing insulating layer IL1 along a common inclined surface may improve mechanical stability at the boundary of the display area DA and the non-display area PA. For example, forming side surfaces of the end IL0a of the lower sensing insulating layer IL0 and the end IL1a of the first sensing insulating layer IL1 with the same inclination may help distribute bending stress more uniformly across this transition zone. This structural configuration may support improved mechanical robustness by reducing the likelihood of delamination or cracking at the interfaces between the stacked insulating layers when the display device is subjected to bending deformation.

A second sensing insulating layer IL2 may be disposed on the first sensing insulating layer IL1. The second sensing insulating layer ILB may include an organic insulating material according to embodiments.

The second sensing insulating layer IL2 may cover the end IL0a of the lower sensing insulating layer IL0 and the end IL1a of the first sensing insulating layer IL1. The second sensing insulating layer IL2 may have a step difference in regions overlapping the end IL0a of the lower sensing insulating layer IL0 and the end IL1a of the first sensing insulating layer IL1.

The end of the second sensing insulating layer IL2 may protrude toward the bending area. Protruding toward the bending area means that the end of the second sensing insulating layer IL2 is formed relatively longer than the end IL0a of the lower sensing insulating layer IL0 and the end IL1a of the first sensing insulating layer IL1. The minimum distance from the end of the second sensing insulating layer IL2 to the display area DA may be greater than the minimum distance from the end of the first sensing insulating layer IL1 to the display area DA.

According to embodiments, the protrusion of the second sensing insulating layer IL2 toward the bending area may serve multiple structural and functional purposes. First, because the second sensing insulating layer IL2 is formed of an organic insulating material, the extended region may function as a compliant buffer layer that absorbs mechanical strain in the bending area. Second, by forming the end of the second sensing insulating layer IL2 to extend beyond the end IL0a of the lower sensing insulating layer IL0 and the end IL1a of the first sensing insulating layer IL1, a stepped transition is created between rigid and flexible layers. This layout may reduce the concentration of mechanical stress at abrupt material interfaces and improve mechanical integrity under repeated bending cycles.

The distance from the end of the second sensing insulating layer IL2 to the end of the lower sensing insulating layer IL0 may be at least about 5 micrometers, and for example, may be about 10 micrometers or more.

A third sensing insulating layer IL3 and a fourth sensing insulating layer IL4 may be sequentially stacked on the second sensing insulating layer IL2. The third sensing insulating layer IL3 may include an inorganic insulating material, and the fourth sensing insulating layer IL4 may include an organic insulating material.

The end IL3a of the third sensing insulating layer IL3 may be positioned on the upper surface of the second sensing insulating layer IL2. The end IL3a of the third sensing insulating layer IL3 may be positioned inward from the end IL0a of the lower sensing insulating layer IL0. In this disclosure, being positioned more inward may mean that the edge is positioned closer to the display area DA. The end IL3a of the third sensing insulating layer IL3 may be positioned closer to the display area DA than the end IL0a of the lower sensing insulating layer IL0. The end IL0a of the lower sensing insulating layer IL0 may protrude more than the end IL3a of the third sensing insulating layer IL3. The end IL3a of the third sensing insulating layer IL3 may be positioned inward from the end IL1a of the first sensing insulating layer IL1. The end IL3a of the third sensing insulating layer IL3 may be positioned closer to the display area DA than the end IL1a of the first sensing insulating layer IL1. The end IL1a of the first sensing insulating layer IL1 may protrude more than the end IL3a of the third sensing insulating layer IL3.

The end IL4a of the fourth sensing insulating layer IL4 may be positioned on the upper surface of the second sensing insulating layer IL2. The end IL4a of the fourth sensing insulating layer IL4 may be positioned inward from the end IL0a of the lower sensing insulating layer IL0. The end IL4a of the fourth sensing insulating layer IL4 may be positioned closer to the display area DA than the end IL0a of the lower sensing insulating layer IL0. The end IL0a of the lower sensing insulating layer IL0 may protrude more than the end IL4a of the fourth sensing insulating layer IL4. The end IL4a of the fourth sensing insulating layer IL4 may be positioned inward from the end IL1a of the first sensing insulating layer IL1. The end IL4a of the fourth sensing insulating layer IL4 may be positioned closer to the display area DA than the end IL1a of the first sensing insulating layer IL1. The end IL1a of the first sensing insulating layer IL1 may protrude more than the end IL4a of the fourth sensing insulating layer IL4.

Ends of the third sensing insulating layer IL3 and the fourth sensing insulating layer IL4 may be aligned with each other. The end IL3a of the third sensing insulating layer IL3 and the end IL4a of the fourth sensing insulating layer IL4 may form one side surface. The end IL3a of the third sensing insulating layer IL3 and the end IL4a of the fourth sensing insulating layer IL4 may form the same inclined surface. The end IL3a of the third sensing insulating layer IL3 and the end IL4a of the fourth sensing insulating layer IL4 may have side surfaces inclined with the same slope. The third sensing insulating layer IL3 may include inorganic insulating materials.

A bending protection layer BPL may be positioned in the non-display area PA. The bending protection layer BPL may cover the end IL2a of the second sensing insulating layer IL2. The end BPLa of the bending protection layer BPL may be disposed on the upper surface of the second sensing insulating layer IL2.

In embodiments, positioning the bending protection layer BPL such that the end BPLa of the bending protection layer BPL is disposed directly on the upper surface of the second sensing insulating layer IL2 may improve structural resilience in the bending area. Because the second sensing insulating layer IL2 is an organic insulating material with relatively high flexibility, it may absorb or diffuse mechanical strain imposed on the bending protection layer BPL during folding. As a result, this configuration may mitigate stress transmission to the more brittle inorganic layers positioned below the second sensing insulating layer IL2, such as the lower sensing insulating layer IL0 and the first sensing insulating layer IL1, thereby improving overall durability of the touch sensing stack.

In an embodiment, the bending protection layer BPL does not overlap the third sensing insulating layer IL3 and the fourth sensing insulating layer IL4. The bending protection layer BPL may be spaced apart from the third sensing insulating layer IL3 and the fourth sensing insulating layer IL4. There may be a space between the end BPLa of the bending protection layer BPL and the end IL3a of the third sensing insulating layer IL3. There may be a space between the end BPLa of the bending protection layer BPL and the end IL4a of the fourth sensing insulating layer IL4.

The bending protection layer BPL may overlap at least portions of the lower sensing insulating layer IL0 and the first sensing insulating layer IL1. However, embodiments are not limited thereto. For example, in an embodiment, the bending protection layer BPL may be positioned on the second sensing insulating layer IL2 while not overlapping the lower sensing insulating layer IL0 and the first sensing insulating layer IL1.

In a case in which the bending protection layer BPL overlaps the third sensing insulating layer IL3 and the fourth sensing insulating layer IL4, it is configured to cover the step difference formed by the ends of the third sensing insulating layer IL3 and the fourth sensing insulating layer IL4. In the non-display area PA where the bending protection layer BPL is disposed, bending of the substrate SUB occurs, and because considerable stress is concentrated at the end of the bending protection layer BPL and the ends of the third sensing insulating layer IL3 and the fourth sensing insulating layer IL4, cracks in the third sensing insulating layer IL3, which is an inorganic insulating material, may be caused. When cracks occur in the third sensing insulating layer IL3, the cracks may propagate to the fourth sensing insulating layer IL4 positioned thereon. Such cracks may cause separation of the bending protection layer BPL covering the ends of the third sensing insulating layer IL3 and the fourth sensing insulating layer IL4.

However, the bending protection layer BPL according to an embodiment may be spaced apart without overlapping with the third sensing insulating layer IL3 and the fourth sensing insulating layer IL4. Therefore, even in a case in which the substrate SUB is bent, the bending protection layer BPL may be stably disposed on the second sensing insulating layer IL2. Thus, embodiments provide a display device with improved reliability and an electronic device including the same.

In an embodiment, because the third sensing insulating layer IL3 includes an inorganic insulating material and the fourth sensing insulating layer IL4 includes an organic insulating material, preventing the end BPLa of the bending protection layer BPL from overlapping the end IL3a of the third sensing insulating layer IL3 and the end IL4a of the fourth sensing insulating layer IL4 may reduce the risk of crack propagation at those locations. For example, spacing the end BPLa of the bending protection layer BPL apart from the ends IL3a and IL4a may isolate the high-strain zone from the edges of stacked layers that may be mechanically vulnerable. This separation may prevent detachment or failure of the bending protection layer BPL, thereby supporting improved reliability in folding-type display devices.

According to FIG. 9, the light blocking layer BM may be positioned closer to the display area DA than the fourth sensing insulating layer IL4. Although the light blocking layer BM is shown as being positioned on the fourth sensing insulating layer IL4 for convenience of illustration, it is not limited thereto and may be positioned, for example, between the third sensing insulating layer IL3 and the fourth sensing insulating layer IL4. In addition, although the light blocking layer BM is shown as a single layer, it may be a layer formed by overlapping two or more color filters as described above.

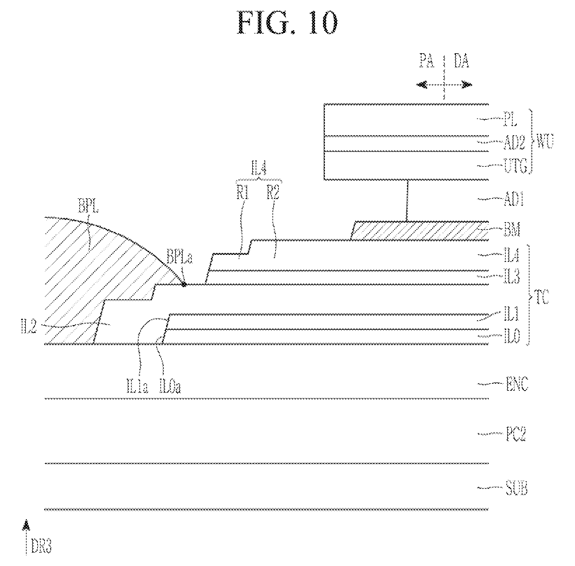

Hereinafter, the stacked structure in the non-display area of an electronic device according to an embodiment will be described with reference to FIGS. 10, 11, and 12. FIGS. 10, 11, and 12 are cross-sectional views of partial areas in the non-display area, respectively. Description of components identical to the aforementioned components will be omitted.

Referring to FIG. 10, the fourth sensing insulating layer IL4 according to an embodiment may include a first region R1 and a second region R2 having different thicknesses. The thickness of the first region R1 may be smaller than the thickness of the second region R2. The first region R1 and the second region R2 may be manufactured in the same process. The first region R1 may be manufactured using a halftone mask, and the second region R2 may be manufactured using a full-tone mask. The fourth sensing insulating layer IL4 may provide a step shape that gradually increases through step differences.

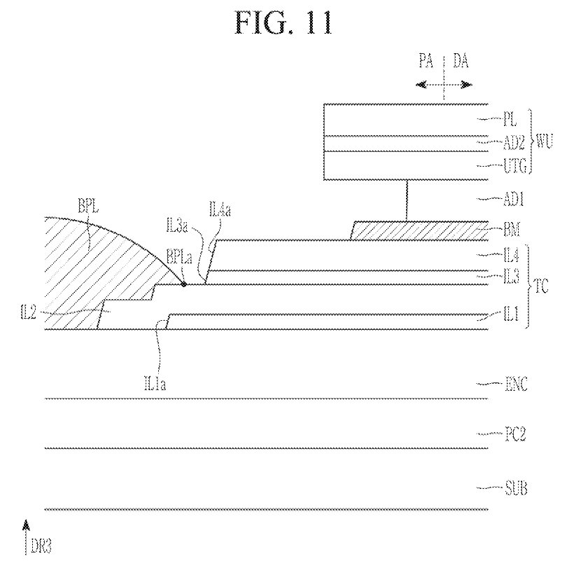

Referring to FIG. 11, the touch sensing portion TC according to an embodiment may include a first sensing insulating layer IL1, a second sensing insulating layer IL2, a third sensing insulating layer IL3, and a fourth sensing insulating layer IL4. The lower sensing insulating layer IL0 may be omitted in an embodiment according to FIG. 11. At least portions of the first sensing insulating layer IL1 and the second sensing insulating layer IL2, and the bending protection layer BPL may be positioned directly above the encapsulation layer ENC.

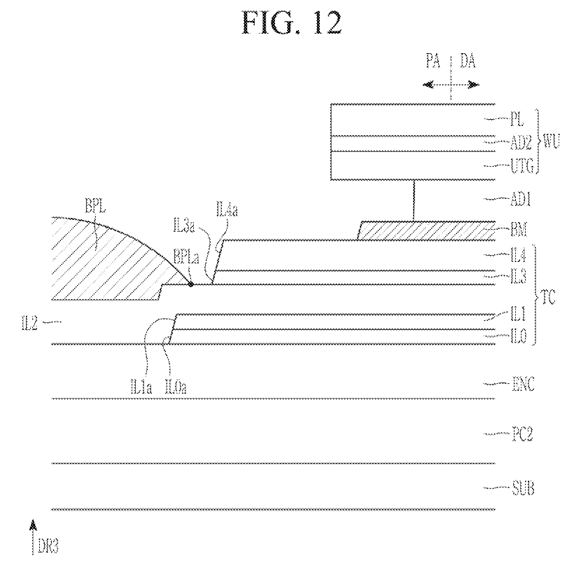

Referring to FIG. 12, the second sensing insulating layer IL2 according to an embodiment may extend to overlap the bending protection layer BPL. Because the second sensing insulating layer IL2 includes an organic insulating material, it may bend flexibly even in case that bent in the bending area together with the bending protection layer BPL.

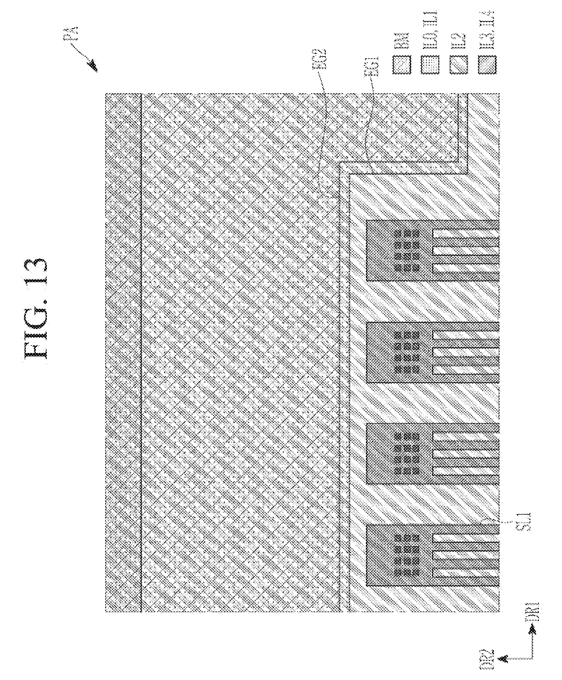

Next, the planar shape in the non-display area will be described with reference to FIGS. 13 to 15. FIGS. 13, 14, and 15 are plan views of sensing insulating layers in the non-display area according to an embodiment, respectively.

First, referring to FIG. 13, a light blocking layer BM may be positioned at a location adjacent to the display area in the non-display area PA according to an embodiment.

A lower sensing insulating layer IL0 and a first sensing insulating layer IL1 may be positioned in the non-display area PA. An edge of the lower sensing insulating layer IL0 and an edge of the first sensing insulating layer IL1 may overlap. The overlapping edges of the lower sensing insulating layer IL0 and the first sensing insulating layer IL1 are referred to as a first edge EG1. The lower sensing insulating layer IL0 and the first sensing insulating layer ILB may expose a portion of the first signal line SL1. According to an embodiment, the first signal line SL1 may transmit a driving voltage or a power voltage, and the like.

A third sensing insulating layer IL3 and a fourth sensing insulating layer IL4 may be positioned in the non-display area PA. An edge of the third sensing insulating layer IL3 and an edge of the fourth sensing insulating layer IL4 may overlap. The overlapping edges of the third sensing insulating layer IL3 and the fourth sensing insulating layer IL4 are referred to as a second edge EG2. The third sensing insulating layer IL3 and the fourth sensing insulating layer IL4 may expose a portion of the first signal line SLB.

The first edge EG1 may surround the second edge EG2. The first edge EG1 may be positioned farther from the edge of the light blocking layer BM compared to the second edge EG2. That is, the shortest distance between the first edge EG1 and the light blocking layer BM may be greater than the shortest distance between the second edge EG2 and the light blocking layer BM.

The second sensing insulating layer IL2 may cover the edge of the lower sensing insulating layer IL0 and the edge of the first sensing insulating layer IL1. The edges of the third sensing insulating layer IL3 and the fourth sensing insulating layer IL4 may be positioned on the second sensing insulating layer IL2. The second sensing insulating layer IL2 may cover at least a portion of the first signal line SL1.

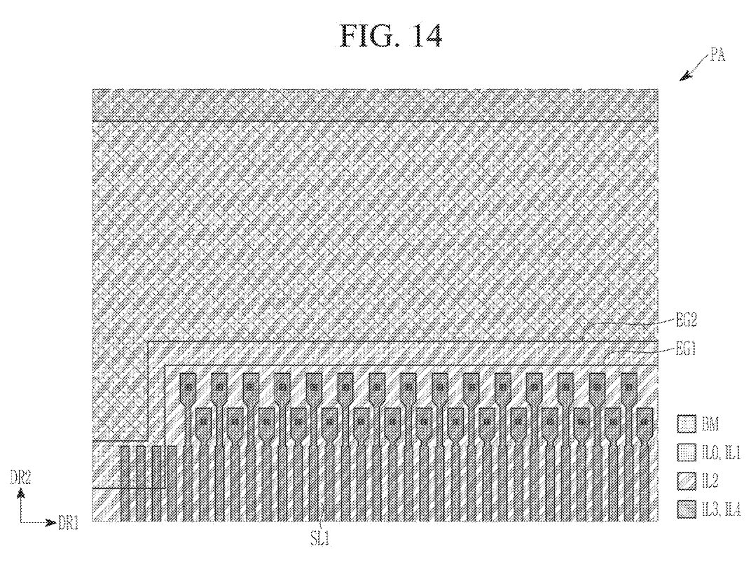

FIG. 14 is an area where a second signal line SL2 is disposed, unlike FIG. 13, in the non-display area PA. A light blocking layer BM may be positioned at a location adjacent to the display area in the non-display area PA according to an embodiment.

A lower sensing insulating layer IL0 and a first sensing insulating layer IL1 may be positioned in the non-display area PA. An edge of the lower sensing insulating layer IL0 and an edge of the first sensing insulating layer IL1 may overlap. The overlapping edges of the lower sensing insulating layer IL0 and the first sensing insulating layer IL1 are referred to as a first edge EG1. The lower sensing insulating layer IL0 and the first sensing insulating layer IL1 may expose at least a portion of the second signal line SL2. According to an embodiment, the second signal line SL2 may transmit data voltages, and the like.

A third sensing insulating layer IL3 and a fourth sensing insulating layer IL4 may be positioned in the non-display area PA. An edge of the third sensing insulating layer IL3 and an edge of the fourth sensing insulating layer IL4 may overlap. The overlapping edges of the third sensing insulating layer IL3 and the fourth sensing insulating layer IL4 are referred to as a second edge EG2. The third sensing insulating layer IL3 and the fourth sensing insulating layer IL4 may expose at least a portion of the second signal line SL2.

The first edge EG1 may surround the second edge EG2. The first edge EG1 may be positioned farther from the edge of the light blocking layer BM compared to the second edge EG2. That is, the shortest distance between the first edge EGB and the light blocking layer BM may be greater than the shortest distance between the second edge EG2 and the light blocking layer BM.

The second sensing insulating layer IL2 may cover the edge of the lower sensing insulating layer IL0 and the edge of the first sensing insulating layer IL1. The edges of the third sensing insulating layer IL3 and the fourth sensing insulating layer IL4 may be positioned on the second sensing insulating layer IL2. The second sensing insulating layer ILB may cover at least a portion of the second signal line SL2.

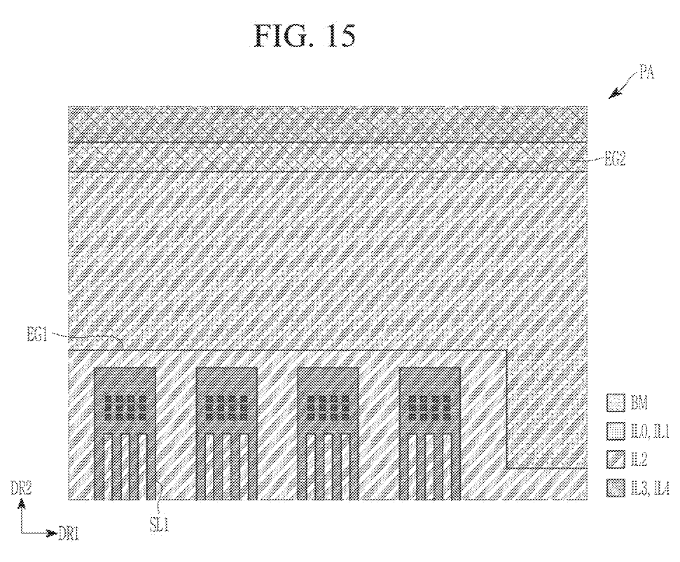

Next, referring to FIG. 15, in the non-display area PA according to an embodiment, the second edge EG2 may be disposed closer to the light blocking layer BM than the first edge EG1. In embodiments according to FIGS. 13 and 14, the second edge EG2 may be positioned closer to the first edge EG1 than to the edge of the light blocking layer BM. In contrast, in an embodiment according to FIG. 15, the second edge EG2 may be positioned adjacent to the light blocking layer BM while being significantly spaced apart from the first edge EG1.

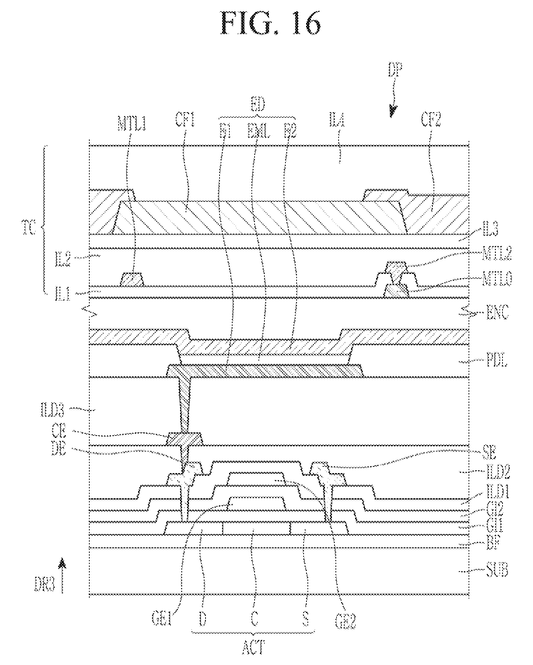

Hereinafter, a pixel in the display area according to an embodiment will be described in further detail with reference to FIGS. 16 to 19. FIGS. 16, 17, 18, and 19 are cross-sectional views of the display area, respectively.

Referring to FIG. 16, the display device DP according to an embodiment may include a substrate SUB. The substrate SUB may include a material having rigid characteristics such as, for example, glass, and the like, or a flexible material that may be bent such as, for example, plastic, polyimide, and the like. The substrate SUB may extend in a first direction DR1 and a second direction DR2.

A buffer layer BF may be positioned above the substrate SUB. The buffer layer BF may planarize the surface of the substrate SUB and block penetration of impurity elements. The buffer layer BF may include an inorganic material, and for example, may include inorganic insulating materials such as silicon nitride (SiNx), silicon oxide (SiOx), and silicon oxynitride (SiOxNy), and the like.

A semiconductor layer ACT may be positioned above the buffer layer BF. The semiconductor layer ACT of the display device according to an embodiment may include, for example, amorphous silicon, polycrystalline silicon, or an oxide semiconductor, and the like.

The semiconductor layer ACT may include a channel region C, a source region S, and a drain region D that are distinguished based on whether impurities are doped. The source region S and the drain region D may be doped with impurities to have conductive characteristics corresponding to conductors.

A first gate insulating layer GI1 may be positioned above the semiconductor layer ACT. The first gate insulating layer GI1 may cover the semiconductor layer ACT and the substrate SUB. The first gate insulating layer GI1 may include inorganic insulating materials such as, for example, silicon nitride (SiNx), silicon oxide (SiOx), and silicon oxynitride (SiOxNy), and the like. The first gate insulating layer GI1 may have a single-layer or multi-layer structure including the above inorganic insulating materials.

A gate electrode GE1 may be positioned above the first gate insulating layer GI1. The gate electrode GE1 may include metals or metal alloys such as, for example, copper (Cu), molybdenum (Mo), aluminum (Al), silver (Ag), chromium (Cr), tantalum (Ta), and titanium (Ti), and the like. The gate electrode GE1 may be a single layer or multiple layers. A region of the semiconductor layer ACT that overlaps with the gate electrode GE1 in a plan view may be the channel region C.

A second gate insulating layer GI2 may be positioned above the gate electrode GE1. The second gate insulating layer GI2 may include inorganic insulating materials such as, for example, silicon nitride (SiNx), silicon oxide (SiOx), and silicon oxynitride (SiOxNy), and the like. The second gate insulating layer GI2 may have a single-layer or multi-layer structure including the above inorganic insulating materials.

A capacitor electrode GE2 may be positioned above the second gate insulating layer GI2. The capacitor electrode GE2 may overlap the gate electrode GE1 to form a capacitor.

A first insulating layer ILD1 may be positioned above the capacitor electrode GE2. The first insulating layer ILD1 may include inorganic insulating materials such as, for example, silicon nitride (SiNx), silicon oxide (SiOx), and silicon oxynitride (SiOxNy), and the like. The first insulating layer ILD1 may have a single-layer or multi-layer structure including the above inorganic insulating materials.

A source electrode SE and a drain electrode DE may be positioned above the first insulating layer ILD1. The source electrode SE and the drain electrode DE are electrically connected to the source region S and the drain region D of the semiconductor layer ACT, respectively, through openings formed in the first insulating layer ILD1, the second gate insulating layer GI2, and the first gate insulating layer GI1.

Accordingly, the aforementioned semiconductor layer ACT, gate electrode GE1, source electrode SE, and drain electrode DE form one transistor. According to embodiments, the transistor may include only the source region and drain region of the semiconductor layer ACT instead of the source electrode SE and the drain electrode DE.

The source electrode SE and the drain electrode DE may include metals or metal alloys such as, for example, aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta), and the like. The source electrode SE and the drain electrode DE may be a single layer or multiple layers. The source electrode SE and the drain electrode DE according to an embodiment may be a triple layer including an upper layer, a middle layer, and a lower layer, and the upper layer and lower layer may include titanium (Ti), and the middle layer may include aluminum (Al).

A second insulating layer ILD2 may be positioned above the source electrode SE and the drain electrode DE. The second insulating layer ILD2 covers the source electrode SE and the drain electrode DE. The second insulating layer ILD2 may planarize the surface of the substrate SUB on which the transistor is provided. The second insulating layer ILD2 may be an organic insulating layer and may include at least one of, for example, polyimide, polyamide, acrylic resin, benzocyclobutene, and phenol resin.

A connection electrode CE may be positioned above the second insulating layer ILD2. The connection electrode CE may electrically connect the drain electrode DE and the first electrode E1. According to embodiments, the connection electrode CE may be omitted.

A third insulating layer ILD3 may be positioned above the connection electrode CE. Although the third insulating layer ILD3 is shown as a single layer, embodiments are not limited thereto. For example, embodiments may include two or more insulating layers.

A first electrode E1 may be positioned above the third insulating layer ILD3. The first electrode E1 may be physically and electrically connected to the connection electrode CE through an opening of the third insulating layer ILD3. Accordingly, the first electrode E1 may receive an output current to be transmitted from the drain electrode DE to the light emitting layer EML.

Hereinafter, descriptions of the aforementioned light emitting element ED, encapsulation layer ENC, and touch sensing portion TC will be omitted.

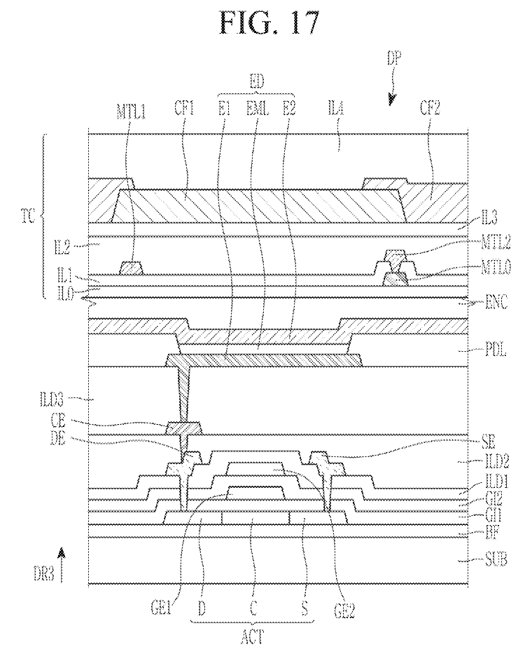

Next, referring to FIG. 17, the touch sensing portion TC according to an embodiment may include a first sensing insulating layer IL1, a second sensing insulating layer IL2, a third sensing insulating layer IL3, and a fourth sensing insulating layer IL4. Compared to an embodiment according to FIG. 16, in an embodiment according to FIG. 17, the touch sensing portion TC does not include a lower sensing insulating layer. The first sensing insulating layer IL1 and the sensing electrode connection portion MTL0 may be positioned directly above the encapsulation layer ENC.

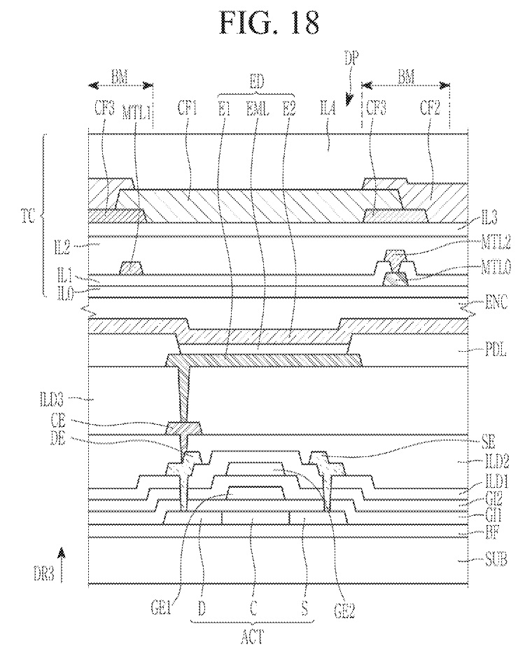

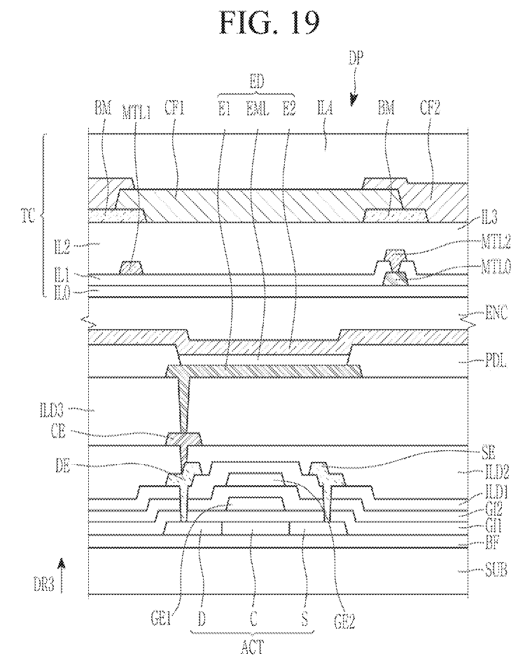

Next, referring to FIG. 18, in an embodiment, the touch sensing portion TC may include a first color filter CF1, a second color filter CF2, and a third color filter CF3. The light blocking layer BM may refer to an area where at least two of the first color filter CF1, the second color filter CF2, and the third color filter CF3 overlap. In an embodiment, as shown in FIG. 19, the touch sensing portion TC may include a light blocking layer BM including a light blocking material.

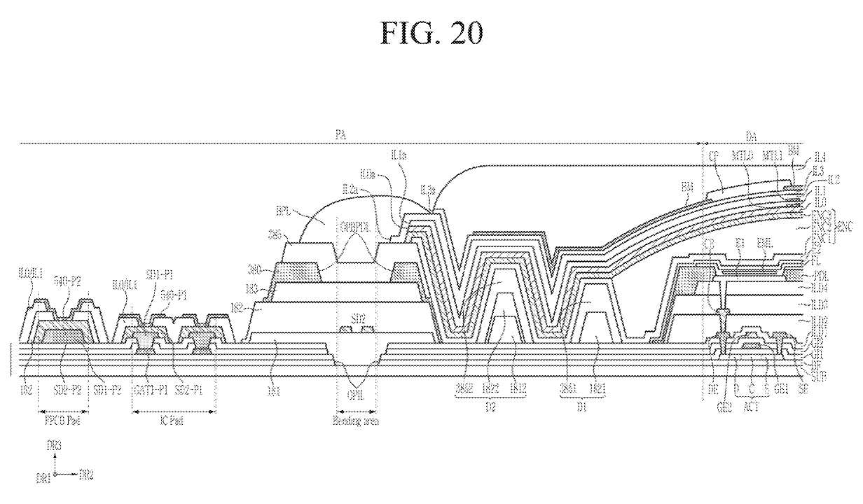

Hereinafter, a cross-section of a display device according to an embodiment will be described with reference to FIG. 20. FIG. 20 is a cross-sectional view illustrating a layered structure of a non-display area according to an embodiment.

FIG. 20 illustrates the display area DA and the non-display area PA, and shows the bending area and pad areas (IC Pad, FPCB Pad) among the non-display area PA. Here, the pad areas (IC Pad, FPCB Pad) show the driver pad portion (IC Pad) and the circuit board pad portion (FPCB Pad). The driver pad portion (IC Pad) is a pad portion for mounting the driver 50 in chip form, and the circuit board pad portion (FPCB Pad) is a pad portion electrically connected to pads of a flexible printed circuit board (FPCB). Here, the driver pad portion (IC Pad) may be electrically connected to conductive layers (fan-out wiring) positioned in the bending area and may also be electrically connected to the driver 50.

First, the layered structure of the bending area in FIG. 20 will be described.

In the bending area, a first organic layer 181 extending from the second insulating layer ILD2 of the display area DA, a second organic layer 182 extending from the third insulating layer ILD3 of the display area DA, a third organic layer 183 extending from the fourth insulating layer ILD4, a fourth organic layer 380 extending from the pixel defining layer PDL, and a spacer 385 may be positioned above the substrate SUB.

As the conductive layer (hereinafter also referred to as fan-out wiring) positioned in the bending area, one conductive layer (second data conductive layer SD2, positioned on the same layer as the connection electrode CE) may be positioned. According to embodiments, at least some of the plurality of organic layers positioned in the bending area may be omitted, and a first data conductive layer SD1 positioned on the same layer as the source electrode SE may be included. In addition, some of the inorganic layers may be positioned. Here, the spacer 385 may be a layer formed of the same material as the spacer formed in the display area DA.

Referring to FIG. 20, in an embodiment, a plurality of inorganic layers BF, GI1, GI2, and ILD1 positioned above the substrate SUB and adjacent to the bending area include an opening OPIL corresponding to the bending area, and inorganic layers are not included in the bending area.

The opening OPIL of the plurality of inorganic layers BF, GI1, GI2, and ILD1 is filled with the first organic layer 181. The first organic layer 181 may be an organic insulating layer including an organic material, and the organic material may include one or more of, for example, polyimide, polyamide, acrylic resin, benzocyclobutene, and phenol resin.

According to embodiments, other conductive layers are not positioned in the bending area except for the second data conductive layer SD2, and a semiconductor layer including a transistor channel is also not included. The second data conductive layer SD2 may be wiring connecting signal lines positioned in the display area DA and the driver 50.

The second data conductive layer SD2 is covered by the second organic layer 182, and the third organic layer 183 is covered above the second organic layer 182. The second organic layer 182 and the third organic layer 183 may include one or more of, for example, polyimide, polyamide, acrylic resin, benzocyclobutene, and phenol resin.

According to embodiments, because the bending area is a non-display area PA, layers corresponding to the light emitting element ED in the display area DA are not included.

The spacer 385 may include photosensitive polyimide (PSPI) and may include a positive type photosensitive organic material.

Although the encapsulation layer ENC is positioned in the display area DA, because the bending area is positioned in the non-display area PA outside the encapsulation layer ENC, in an embodiment, the encapsulation layer ENC is not positioned in the bending area. Because the bending area is positioned in the non-display area PA, the light blocking layer BM and color filter CF positioned in the display area DA are also not positioned.

According to embodiments, layers included in the touch sensing portion TC are not positioned in the bending area. A bending protection layer BPL positioned above the spacer 385 may be positioned in the bending area.

The structure of the bending area according to embodiments has been described above. For convenience of explanation, a further detailed description of the display area DA in FIG. 20 will be omitted. Hereinafter, the non-display area PA between the bending area and the display area DA will be described.

The non-display area PA may include a plurality of dams D1 and D2. Although FIG. 20 shows two dams (one first dam D1 and one second dam D2), embodiments are not limited thereto. For example, according to embodiments, two or more dams may be included. The plurality of dams D1 and D2 may be positioned above a plurality of inorganic layers (buffer layer BF, first gate insulating layer GI1, second gate insulating layer GI2, and first insulating layer ILD1) extending from the display area DA.

The first dam D1 is positioned closer to the display area DA than the second dam D2, and the first dam D1 may have a lower height than the second dam D2.

The first dam D1 may include a 1-1 sub-dam 1821 and a 1-2 sub-dam 3851. The 1-1 sub-dam 1821 may be positioned on the same layer as the third insulating layer ILD3 positioned in the display area DA and may include the same material. The 1-1 sub-dam 1821 may be formed in the same process as the third insulating layer ILD3 positioned in the display area DA. The 1-2 sub-dam 3851 may be positioned on the same layer as the spacer (or pixel defining layer) positioned in the display area DA and may include the same material. The 1-2 sub-dam 3851 may be formed in the same process as the spacer (or pixel defining layer) positioned in the display area DA.

The second dam D2 may include a 2-1 sub-dam 1812, a 2-2 sub-dam 1822, and a 2-3 sub-dam 3852. The 2-1 sub-dam 1812 may be positioned on the same layer as the second insulating layer ILD2 positioned in the display area DA and may include the same material. The 2-1 sub-dam 1812 may be formed in the same process as the second insulating layer ILD2 positioned in the display area DA. The 2-2 sub-dam 1822 may be positioned on the same layer as the third insulating layer ILD3 positioned in the display area DA and may include the same material. The 2-2 sub-dam 1822 may be formed in the same process as the third insulating layer ILD3 positioned in the display area DA. The 2-3 sub-dam 3852 may be positioned on the same layer as the spacer (or pixel defining layer) positioned in the display area DA and may include the same material. The 2-3 sub-dam 3852 may be formed in the same process as the spacer (or pixel defining layer) positioned in the display area DA.

FIG. 20 illustrates an embodiment in which the first dam D1 is formed in a double-layer structure and the second dam D2 is formed in a triple-layer structure. However, embodiments are not limited thereto. For example, according to embodiments, the first dam D1 may be formed in a triple-layer structure and the second dam D2 may be formed in a quadruple-layer structure.

A first inorganic encapsulation layer ENC1 extending from the display area DA is positioned above the first dam D1 and the second dam D2. In addition, an organic encapsulation layer ENC2 extending from the display area DA is positioned above the first inorganic encapsulation layer ENC1, and the organic encapsulation layer ENC2 may be positioned above the first dam D1, but the organic encapsulation layer ENC2 is not positioned above the second dam D2 according to an embodiment. The first dam D1 may control the spreading of material in the process of forming the organic encapsulation layer ENC2. The organic encapsulation layer ENC2 may have a form that fills the space between the end of the display area DA and the first dam D1. A second inorganic encapsulation layer ENC3 overlapping the entire surface of the substrate SUB may be positioned on the organic encapsulation layer ENC2. Above the second dam D2 where the organic encapsulation layer ENC2 is not positioned, the first inorganic encapsulation layer ENC1 has a structure in contact with the second inorganic encapsulation layer ENC3. The structure where the first inorganic encapsulation layer ENC1 contacts the second inorganic encapsulation layer ENC3 may block entry of moisture and oxygen into the device.

Components of the touch sensing portion may be positioned above the second inorganic encapsulation layer ENC3. In the non-display area PA, a lower sensing insulating layer IL0, a first sensing insulating layer IL1, a second sensing insulating layer ILB, a third sensing insulating layer IL3, and a fourth sensing insulating layer IL4 extending from the display area DA may be positioned. In an embodiment, connection wiring electrically connected to the sensing electrodes MTL1 and MTL2 may be positioned. The connection wiring may be electrically connected to the driver 50.

The end IL0a of the lower sensing insulating layer IL0 and the end IL1a of the first sensing insulating layer IL1 may be positioned in the non-display area PA between the bending area and the display area DA. Ends of the lower sensing insulating layer IL0 and the first sensing insulating layer ILB may be aligned. The lower sensing insulating layer IL0 and the first sensing insulating layer IL1 may extend to between the second dam D2 and the bending area.

The second sensing insulating layer IL2 may extend from the display area DA to the non-display area PA. The second sensing insulating layer IL2 may cover ends of the lower sensing insulating layer IL0 and the first sensing insulating layer IL1. The second sensing insulating layer IL2 may extend to an area overlapping the bending protection layer BPL. The end IL2a of the second sensing insulating layer IL2 may overlap the bending protection layer BPL.

The third sensing insulating layer IL3 and the fourth sensing insulating layer IL4 may extend from the display area DA to the non-display area PA. The end IL3a of the third sensing insulating layer IL3 and the end of the fourth sensing insulating layer IL4 may extend to between the end of the first sensing insulating layer IL1 and the display area DA. Ends of the third sensing insulating layer IL3 and the fourth sensing insulating layer IL4 may be aligned with each other. Ends of the third sensing insulating layer IL3 and the fourth sensing insulating layer IL4 may be spaced apart from the bending protection layer BPL.

A light blocking layer BM may be positioned on the third sensing insulating layer IL3. The light blocking layer BM may be a single layer including a light blocking material according to embodiments, or may be a layer where two or more color filters CF overlap. The light blocking layer BM may extend to the non-display area PA in addition to the display area DA. The end of the light blocking layer BM may be positioned between the bending area and the display area DA. The end of the light blocking layer BM may be positioned between the end of the third sensing insulating layer IL3 and the display area DA.

The fourth sensing insulating layer IL4 may extend from the display area DA to the non-display area PA and may be formed continuously. The fourth sensing insulating layer IL4 may be positioned in a partial area of the non-display area PA and may not be positioned in the bending area and pad areas (driver pad portion (IC Pad) and circuit board pad portion (FPCB Pad)).

The bending protection layer BPL according to an embodiment may overlap the second sensing insulating layer IL2 while being spaced apart from the third sensing insulating layer IL3 and the fourth sensing insulating layer IL4. Therefore, even in a case in which the substrate SUB is bent, the bonding between the bending protection layer BPL and the second sensing insulating layer IL2 may be stably provided, which may improve the reliability of the display device and the electronic device.

Hereinafter, the structure of the pad areas (driver pad portion (IC Pad) and circuit board pad portion (FPCB Pad)) according to FIG. 20 will be described.

The driver pad portion IC Pad is shown as a quadruple-layer structure. The driver pad portion IC Pad may include a second additional pad electrode GATB-P1 positioned on the same layer as the gate electrode GE1, a first additional pad electrode SD1-P1 positioned on the same layer as the source electrode SE, a first pad electrode SD2-P1 positioned on the same layer as the connection electrode CE, and a second pad electrode 540-P1 positioned on the same layer as the sensing electrodes MTL1 and MTL2.

The first gate insulating layer GI1 is positioned below the second additional pad electrode GAT1-P1, and the second gate insulating layer GI2 and the first insulating layer ILD1 are positioned between the second additional pad electrode GAT1-P1 and the first additional pad electrode SD1-P1. The lower sensing insulating layer IL0 and the first sensing insulating layer IL1 may be positioned between the first pad electrode SD2-P1 and the second pad electrode 540-P1.

According to embodiments, the driver pad portion IC Pad may have a double-layer structure or a triple-layer structure. At least one of the aforementioned second additional pad electrode GAT1-P1, first additional pad electrode SD1-P1, first pad electrode SD2-P1, and second pad electrode 540-P1 may be omitted.

In addition, the circuit board pad portion FPCB Pad is shown as a triple-layer structure. The circuit board pad portion FPCB Pad may include a first additional pad electrode SD1-P2 positioned on the same layer as the source electrode SE, a first pad electrode SD2-P2 positioned on the same layer as the connection electrode CE, and a second pad electrode 540-P2 positioned on the same layer as the sensing electrodes MTL1 and MTL2. Sensing insulating layers IL0 and IL1 may be positioned between the first pad electrode SD2-P2 and the second pad electrode 540-P2 in the circuit board pad portion FPCB Pad.

According to embodiments, the circuit board pad portion FPCB Pad may have a double-layer structure, and in the double-layer structure, any one of the first additional pad electrode SD1-P2, the first pad electrode SD2-P2, and the second pad electrode 540-P2 may be omitted.

According to embodiments of the present disclosure, in a structure for bending a substrate, the bending protection layer is spaced apart from the third sensing insulating layer and the fourth sensing insulating layer, which may enable stable contact between the bending protection layer and the touch sensing portion. Accordingly, a display device with improved reliability and an electronic device including the same may be provided.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a substrate including a display area and a non-display area;
a pixel circuit portion disposed on the substrate and overlapping the display area;
an encapsulation layer disposed on the pixel circuit portion; and
a touch sensing portion disposed on the encapsulation layer,
wherein the touch sensing portion includes:
a first sensing insulating layer;
a second sensing insulating layer disposed on the first sensing insulating layer;
a third sensing insulating layer disposed on the second sensing insulating layer;
a fourth sensing insulating layer disposed on the third sensing insulating layer; and
a sensing electrode disposed between the first sensing insulating layer and the second sensing insulating layer,
wherein, in the non-display area, an end of the fourth sensing insulating layer is positioned inward from an end of the second sensing insulating layer.

2. The display device of claim 1, wherein an end of the third sensing insulating layer is positioned inward from the end of the second sensing insulating layer.

3. The display device of claim 2, wherein the end of the third sensing insulating layer and the end of the fourth sensing insulating layer overlap.

4. The display device of claim 2, wherein the end of the third sensing insulating layer and the end of the fourth sensing insulating layer form a same inclined surface.

5. The display device of claim 1, wherein the second sensing insulating layer covers an end of the first sensing insulating layer.

6. The display device of claim 5, wherein an end of the third sensing insulating layer is positioned inward from the end of the first sensing insulating layer.

7. The display device of claim 5, wherein the end of the fourth sensing insulating layer is positioned inward from the end of the first sensing insulating layer.

8. The display device of claim 1, wherein
the first sensing insulating layer and the third sensing insulating layer include an inorganic insulating material, and
the second sensing insulating layer and the fourth sensing insulating layer include an organic insulating material.

9. The display device of claim 8, wherein the second sensing insulating layer and the fourth sensing insulating layer include a same material.

10. The display device of claim 1, wherein the touch sensing portion further includes a lower insulating layer positioned between the first sensing insulating layer and the encapsulation layer.

11. The display device of claim 10, wherein ends of the lower insulating layer and the first sensing insulating layer overlap.

12. The display device of claim 1, further comprising:
a bending protection layer overlapping at least a portion of the second sensing insulating layer,
wherein the bending protection layer covers at least a portion of an upper surface of the second sensing insulating layer,
wherein a portion of the substrate that overlaps the bending protection layer has a curved shape.

13. The display device of claim 1, further comprising:
a light blocking layer positioned in the non-display area,
wherein a minimum distance from the light blocking layer to the second sensing insulating layer is greater than a minimum distance from the light blocking layer to the fourth sensing insulating layer,
wherein the light blocking layer is an area where at least two of a first color filter, a second color filter, and a third color filter having different colors overlap.

14. A display device, comprising:
a substrate including a display area and a non-display area;
a pixel circuit portion disposed on the substrate;
an encapsulation layer disposed on the pixel circuit portion; and
a touch sensing portion disposed on the encapsulation layer,
wherein the touch sensing portion includes:
a first sensing insulating layer;
a second sensing insulating layer disposed on the first sensing insulating layer;
a third sensing insulating layer disposed on the second sensing insulating layer;
a fourth sensing insulating layer disposed on the third sensing insulating layer; and
a sensing electrode disposed between the first sensing insulating layer and the second sensing insulating layer,
wherein, in the non-display area, an end of the fourth sensing insulating layer overlaps an upper surface of the second sensing insulating layer.

15. The display device of claim 14, wherein an end of the third sensing insulating layer and the end of the fourth sensing insulating layer overlap.

16. The display device of claim 14, wherein an end of the third sensing insulating layer is positioned inward from an end of the second sensing insulating layer, and the end of the fourth sensing insulating layer is positioned inward from the end of the second sensing insulating layer.

17. The display device of claim 14, wherein the touch sensing portion further includes a lower insulating layer positioned between the first sensing insulating layer and the encapsulation layer, and ends of the lower insulating layer and the first sensing insulating layer overlap.

18. The display device of claim 14, further comprising:
a bending protection layer overlapping at least a portion of the second sensing insulating layer,
wherein a portion of the substrate that overlaps the bending protection layer has a curved shape.

19. An electronic device, comprising:
a display device; and
a cover window positioned on the display device,
wherein the display device includes:
a substrate including a display area and a non-display area;
a pixel circuit portion disposed on the substrate;
an encapsulation layer disposed on the pixel circuit portion; and
a touch sensing portion disposed on the encapsulation layer,
wherein the touch sensing portion includes:
a first sensing insulating layer;
a second sensing insulating layer disposed on the first sensing insulating layer;
a third sensing insulating layer disposed on the second sensing insulating layer;
a fourth sensing insulating layer disposed on the third sensing insulating layer; and
a sensing electrode disposed between the first sensing insulating layer and the second sensing insulating layer,
wherein, in the non-display area, an end of the fourth sensing insulating layer is positioned on an upper surface of the second sensing insulating layer.

20. The electronic device of claim 19, further comprising:
a protective layer positioned on a rear surface of the substrate.
